(19) United States
(12) Patent Application Publication
(10) Pub. No.: US 2008/0203384 A1
(43) Pub. Date: Aug. 28, 2008

(54) Method of Manufacturing an Electrical Element

(75) Inventors: Hylke Broer Akkerman, Groningen (NL); Bert De Boer, Groningen (NL); Paulus Wilhelmus Maria Blom, Groningen (NL); Dagobert Michel De Leeuw, Eindhoven (NL); Thomas Cleophas Theodorus Geuns, Eindhoven (NL); Eugenio Cantatore, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/996,600

(22) PCT Filed: Jul. 21, 2006
(86) PCT No.: PCT/IB06/52510

§ 371 Date: Jan. 24, 2008

(30) Foreign Application Priority Data
Jul. 27, 2005 (EP) 05106926.8

(51) Int. Cl. H01L 51/40; H01L 51/05

(52) U.S. Cl. 257/40; 438/99; 257/E21.159; 257/E51.025

(57) ABSTRACT

The element (50) comprises a first electrode (51), a self-assembled system (52), which is or comprises a monolayer an a second electrode (54). A polymeric contact layer (53) that has been deposited wet-chemically is present between the self-assembled system (52) and the second electrode (54). Suitably, both the self-assembled system (52) and the contact layer (53) are provided in a cavity (40).

The invention relates to a method of manufacturing an electrical element comprising a first and a second electrode and an intermediate self-assembled system, as well as to a method of manufacturing an electronic device comprising such an element.

The invention further relates to an electrical element with a first and a second electrode and an intermediate self-assembled system, as well as electronic devices therewith.

The primary examples of self-assembled systems are self-assembled monolayers, also referred to as SAMs. Such monolayers and their preparation are known per se. Particularly, an organic compound with a chain and an end group is applied to a surface. This leads to bonding of the end group to the surface, while the chain are oriented substantially perpendicular to the surface in an array-like manner. One example of an organic compound is a thiol, for instance C₁₆—SH, and one example of a surface is gold.

The study of self-assembled monolayers has brought up several applications. In a first application, the monolayer is provided in a patterned manner on the surface. It is subsequently used as an etch resist to structure the surface, particularly gold. This technique is known as microcontactprinting. Other applications are for instance in the area of biosensors, wherein the monolayer can protect a selective surface, or wherein a label or a compound to be measured is provided on a surface as a self-assembled monolayer.

In a further application, the limited thickness of the self-assembled monolayer is exploited for electrical purposes. It is generally known that the capacitance of a capacitor decreases with the distance between the first and second electrodes, and thus the thickness of the intermediate dielectric. Using the monolayer as the dielectric will thus result in a capacitor with a very high capacitance. Such a system is for instance known from Reed et al, Science, 278(1997), 252. Here, use is made of Ar—Ac—Nar—Nar—Ac—Ar—S as the monolayer, wherein Ar is phenylene, Ac is acetylene and Nar is a 2-amino-1,6-phenylene.

Although this application is really interesting, it turns out problematic to manufacture properly working capacitors. After having formed such capacitor with a gold bottom electrode, a thiol monolayer and a vapor deposited or sputtered gold top electrode, it turns out that there is a short-circuit formed in the capacitor. In other words, there is an area, where the monolayer has been interrupted and the first electrode contacts the second electrode directly. This could be the result of a deficient manufacture. Alternatively, it could be that the resulting capacitor has a very limited breakdown voltage, so that the application of any voltage over the monolayer is sufficient to form a short-cut through the monolayer. Moreover, the resulting monolayer has a substantial negative differential resistance (NDR). When increasing the applied bias voltage from 0 to 2.5 Volt, the current density increases in a first section between 0 and 1 V, decreases in a second section between 1 and 1.5 Volt and finally increases again. This is a undesired effect which hampers practical applications.

It is therefore a first object of the invention to provide a method of manufacturing an electrical element of the kind mentioned in the opening paragraph, which results in a properly working element that is able to withstand a minimal voltage difference over the self-assembled system.

This object is achieved in that a composition that comprises an organic material is applied by wet-chemical deposition on the self-assembled system, so as to form a polymer contact layer, and the second electrode is deposited on the electrically conductive contact layer.

The inventors of the present invention have observed, in the process leading to the invention, that the malfunctioning of the capacitor is caused by the vapor deposition of the second electrode. The deposited gold particles are small enough to diffuse between the perpendicularly oriented chains of the monolayer. This diffusion or hole-forming process in the monolayer is enhanced in that the gold particles do not adhere properly to the apolar organic chains of the monolayer. That the gold particles can diffuse into the monolayer is understood to be the result of the deposition method, e.g. sputtering or vapor deposition. This deposition method provides the particles with considerable energy. Thus even if the molecules of the monolayer would be provided with two end-groups on opposite sides of the molecules, then still the gold particles would have sufficient energy so as to diffuse along the exposed end groups into the chain.

The resulting problem of the creation of an improved top electrode was then solved by the use of an additional contact layer that is not part of the dielectric, and that does not introduce any electrical artefacts into the electric element, such as a lack of uniformity over the electrode surface, or a substantially increased contact resistance. Such a contact layer needs to have a sufficient adhesion to the monolayer and its application may not lead to deformation of the monolayer. It also must have a proper adhesion to the top electrode thereon. Additionally, the use of the contact layer may not lead to malfunctioning during use, e.g. the capacitor must have a sufficient breakdown voltage.

This contact layer was chosen to comprise a polymer material. Polymeric materials are visco-elastic systems, but this is not problematic for the stability of the self-assembled system. In fact, movement of the polymeric molecules of the contact layer is limited by the presence of the other molecules in the contact layer. Only one-dimensional movement of the polymer molecules in the direction of the chain is present, instead of the three-dimensional movement allowed in solutions and other systems. This process of movement is known in theoretical literature as reptation.

Furthermore, the contact layer is applied by wet-chemical deposition. When one would apply the contact layer from the gas phase, one deposits essentially individual molecules. This still has the risk of diffusion into the self-assembled system. In general, the wet-chemically deposited material will be the polymer of the contact layer. It is however not excluded, that the polymerization takes place only after the deposition of organic material on the self-assembled system. A suitable process hereto is known from EP-A 615256.

The contact layer was further chosen to be electrically conducting. Intrinsically electrically conducting polymers are however not known. The conduction results from the provision of dopants to the polymers. It would appear that these dopants can diffuse into the self-assembled system and can still lead to breakdown of the electrical element. However, the inventors have understood that the dopants in electrically conducting organic material are bonded to the chain of the material, and thus cannot diffuse freely throughout the contact layer and into the self-assembled system. It is herein observed that it is not excluded that the contact layer is rendered electrically conductive only after its deposition on the self-assembled system.

In view of its electrical conductivity, the contact layer is suitably patterned. It will be understood that there is no direct contact between the contact layer and the first electrode within the element, as this would lead to a short. However, this may be different outside the element; the contact layer may for instance be part of a vertical interconnect and have an interface with a conductor track leading to the first electrode.

Suitably, the self-assembled system of the invention comprises a monolayer that is formed by self-assembly. This is found to be suitable for a proper adhesion of the self-assembled system to the first electrode. However, use of another method for deposition of a monolayer, such as Langmuir-Blodgett deposition, is not excluded. Moreover, the self-assembled system may well comprise more than a single monolayer, as will be discussed below.

It is highly suitable that the organic material is deposited in a polar solvent, such that the solvent is not attracted to the organic, generally apolar chains of the self-assembled system. If the solvent were attracted to the chains, the diffusion of the molecules of the contact layer between the molecules of the self-assembled system was enabled, leading to an increased risk of breakdown. Suitable solvents are for instance water, alcohols, organic acids, such as formic acid and acetic acid, dimethylsulfoxide, dimethylformamide, acetonitrile, acetone, N-methyl-2-pyrrolidone, and any suitably mixtures thereof.

The contact layer may be deposited in several manners. In a first embodiment, a material is chosen for the contact layer, which can be made electrically conducting locally. Such a material is for instance the polyaniline as known from WO-A 99/10939. The contact layer is then deposited and made electrically conductive at the area of the self-assembled system. Outside this area, the material may be removed, but that is not necessary.

Secondly, and most preferred, the contact layer is deposited into a previously created cavity of dielectric material. Suitably, the dielectric material is a photoresist material. This has turned out a reliable method. It is then advantageous for practical reasons, that the cavity is created before the monolayer is deposited.

Thirdly, the substrate with the first electrode may have a three-dimensional shape, such as a trench shape, or a cavity shape. Trenches can be suitably made in a semiconductor substrate by dry etching, and the use of such trenches for the creation of capacitors is known per se. Cavities in which the first electrode extends on several surfaces can be made by deformation of a foil, such as for instance a foil of a sacrificial layer with copper conductors. Such a foil and its deformation is known per se in the field of packaging.

The material of the contact layer is most preferably an electrically conducting polymer, e.g. a polymer material in which the conductivity arises as a result of the interaction of the dopants with the polymer material, and particularly with electrically conducting groups therein. Examples of these materials are polyanilines, polythiophenes, polyacetylenes, polypyrrols which may be substituted with side groups such as alkoxy, alkyl, aryl and the like. Alternatively, the material of the contact layer may be a material in which electrically conductive elements are incorporated, such as epoxies or other polymers filled with silver, graphite or the like. These latter materials are however distinctly less preferred in that the uniformity of the layer is substantially smaller, and hence the uniformity of the element over its surface area is reduced.

More preferably, the material of the contact layer is an electrically conducting polymer in combination with a polyacid as an inherent dopant. This material has the advantage that it may be deposited with water as the solvent—insofar as the composition of the conducting polymer with the polyacid in water may be called a solution, instead of a suspension or emulsion.

Most preferably, use is made of a poly-(3,4-substituted-thiophene) as the conducting polymer. The best known example of this class of polymers is the one with a 3,4-alkylenedioxy-substitution, that is usually referred to as PEDOT. The alkylenegroup is suitably an optionally substituted C₁-C₄-alkylene group and preferably chosen herein from the group consisting of an optionally C₁ to C₁₂-alkyl- or phenylsubstituted methylene group, an optionally C₁ to C₁₂-alkyl- or phenylsubstituted 1,2-ethylene group, a 1,3-propylene group and a 1,2-cyclohexylene group. Additives may be added to increase the conductivity and processing behavior, such as surfactant.

In one example, a photochemical initiator is added to the composition of the polyacid and the electrically conducting polymer. This initiator is then used to allow cross-linking of the material after deposition. The cross-linking has the advantage that the material cannot be dissolved anymore in its original solvent, and thus allows to use a larger variety of solvent in further processing steps. Moreover, the cross-linking allows to do an after treatment with a polyalcohol, such as sorbitol, to increase the electrical conductivity of the layer. This process is known from WO-A 01/20691. A further advantage of the initiator is that bonds between the self-assembled system and the contact layer may be formed.

Several methods may be used for the deposition of the contact layer, and suitably its patterning. In one example, use is made of spin- or webcoating and a subsequent etching step. This etching step may be carried out after provision of the second electrode, such that the second electrode acts as the etching mask for the patterning of the contact layer. In another example, use is made of a spin- or webcoating the contact layer. It is then subsequently patterned. One way to do this is the inclusion of a photochemical initiator in the composition for the contact layer, to irradiate it subsequently according to the desired pattern, and to remove the undesired areas, which most suitably are the non-irradiated areas. Another way of doing this is the provision of the contact layer in a cavity, and the removal of material outside the cavity. In a further example, use is made of printing the contact layer; suitably inkjetprinting is used thereto.

The second electrode may comprise any electrically conducting material. The choice of the material is mainly determined by the integration into an electronic device. Gold may be readily deposited. It allows the provision of further self-assembled monolayers. Gold furthermore allows the provision of solder materials, if for instance the electric element is made part of a circuit board, a smart card or a package substrate, of if the electrical element is provided just below bonding pads. Copper and aluminum, as well as the usual alloys thereof, are standard materials for the provision of interconnects in integrated circuits, and also in other components such as displays, sensors, printed circuit boards, and the like. Conductive oxides, such as indium-tin-oxide are transparent, and are used as conductive materials in optoelectronic applications, such as displays. Alternatively, electrically conductive organic materials could be used for the second electrode, although the conductivity of these materials is still rather low for their use as interconnect.

The materials of the first electrode and of the compound in the self-assembled system bonded to the first electrode are chosen so as to form an adequate bond. Suitable materials for the first electrode include gold, copper, conductive oxides, aluminum, doped silicon GaAs, other III-V semiconductors, mercury, nickel, platinum, palladium and the like. The corresponding compounds differ with respect to the chosen end groups, such as known per se to the skilled person, and for instance mentioned in Whitesides and Xia, Angewandte Chem. Int. Ed., 37, 1998, 550-575. Examples are hereof thiols, isocyanates, disulfides, thioethers, thioacids, which molecules may be provided with additional end groups.

More preferably, the self-assembled system is provided with a first and a second functional group, which first functional group is part of a compound which forms the monolayer and is after the self-assembly bonded to the first electrode, which a second functional group is exposed on the self-assembled system and enables formation of a bond with the organic contact layer. Providing a bond between the self-assembled system and the organic contact layer was found not to be necessary, but very suitable for the stability and performance of the element.

This bond may be a chemical bond, in that the second functional group is incorporated into the network of the organic contact layer. This may be achieved with crosslinking with the help of a photochemical initiator, but also with bonding sites in the contact layer. Suitable bonding sites are based on the formation of a bond by condensation reaction. If the second functional group is a thiol or an alcohol or a nitride (—NH₂), a suitable bonding site is for instance an acid group. If the second functional group is an acid, the bonding site is suitably a base.

The bond may also be a physical bond, with as preferred example hydrogen bonding. A system with for instance a polyacid has sufficient groups that allow hydrogen bonding. This is also and additionally the case, if the poly-3,4-substituted thiophenes, such as PEDOT as the electrically conducting polymer.

It is observed that the compound that adheres to the first electrode, is generally a monolayer. It is however not excluded to use a mixture of monolayer molecules. Particularly, the compounds may have a different chain length. The mixture may stabilize the self-assembled system, particularly for electrically interesting monolayer compounds that otherwise may not have a good mechanical stability. An example is for instance a mixture of a octanethiol and a hexanethiol, which forms an extremely thin monolayer. As will be understood, the thiol functional group may herein be replaced by another functional group, and the compound with a single functional group may be replaced by a compound with two functional groups.

Suitably the manufacture of the electrical element constitutes one step in the manufacture of an electronic device. Such electronic device may comprise a plurality of the electrical elements as made according to the invention and suitably also other passive and active elements. The elements of the invention may also be integrated into an array, which allows the manufacture of memories. In the case that the electronic device is an integrated circuit, it appears suitable to integrate the element of the invention within the interconnect structure, or even more suitable on top of the passivation layer. It will be understood that the first and second electrode are suitably provided as part of layers in which further patterns are defined, such as interconnects, electrodes, bond pads and the like. The manufacture hereof is carried out suitably on plate-level after which individual devices are separated from each other.

It is another object of the invention to provide an electrical element comprising a self-assembled system between a first and a second electrode. This object is achieved in that a polymeric, electrically conductive contact layer is present between the self- assembled system and the second electrode.

As explained above, the use of a polymeric contact layer allows the manufacture of such element in a reliable manner and leads to an element that has a high capacitance density without an unpractically low breakdown voltage or any shorts. The element is particularly obtainable with the method of the invention, and discussions and embodiments discussed with reference to the method also apply to the element and vice versa.

The self-assembled system is suitably merely a single monolayer, such as an alkanethiol, or an alkanedithiol. Evidently, the monolayer may have other end groups and be a isocyanate, disulfide, thioether, thioacid, hydroxysilane, chlorosilane. The compound is suitably a self-assembled monolayer with an alkane chain, although the prior art makes clear that alternatives are available. As will be understood by the person skilled in the art, the alkanes are in general C6-C20 alkanes, but the main chain can contain various other structural or functional groups, such as amide, amino, ester, ether, keto, silyl groups etc. These groups may constitute a major part of the chain, such as in oligo(ethyleneglycol) groups (OCH2CH2)n. Moreover, the alkanes are preferably linear, but methyl or ethyl side groups could be present. The alkanes could be branched or substituted in any other way. However, in most cases a less good packing of the monolayer is obtained with non-linear alkyl chains. Exceptions are chains that are modified with hydrogen-bonding functional groups. These hydrogen-bonding functional groups are capable of significantly increasing the interaction between the individual monolayer forming molecules. Therewith, they may cause a stabilization of the monolayer. The resulting element is then a capacitor. However, it is not limited thereto. It was herein observed that the current density depends on the chain length of the monolayer inversely exponential: while for an alkanethiol with a chain length of 20 Angstroms a current density of about 10⁵ A/m² was found at a bias voltage of 0.2 V, the current density for an alkanethiol with a chain length of 15 Angstroms was more than 10⁸ A/m² for the same bias voltage of 0.2 V.

In a second example, the self-assembled system comprises not merely a single monolayer, but two or a couple of monolayers that have been provided by self-assembly on each other. In this manner a bilayer or multilayer in which the individual layers have different properties may be created. Alternatively, it can be used to create a capacitor with an increased breakdown voltage. A preferable version of such bilayer or multilayer would be one that includes a junction. This may be enabled in that a p-type organic semiconductor material is used for the first monolayer, and a n-type organic semiconductor material is used for the second monolayer. The p-type material is for instance a oligothiophene and the n-type material a C₆₀-buckyball type of material. The oligothiophene itself does not have suitable functional groups for the formation of self-assembled monolayers. It may however be provided with apolar chains, and hence also with apolar chains with functional groups. A suitable synthesis of the provision of an oligothiophene with apolar chains is described in the non-prepublished application EP05101249.0 (PHNL050166).

In a third example, the self-assembled system comprises as a monolayer compound a material that includes both p-type groups and n-type groups, or alternatively donor and acceptor groups. Preferably such groups are separated by an apolar group, such as alkyl (—R—) or orthoalkylene (—OR—, —ORO—) and the like. Molecules with specific characteristics may be included in a larger network or apolar chain such as known from WO-A 2003/079400.

In a fourth example, the self-assembled system comprises a nanomaterial, and particularly a carbon nanotube or a semiconductor nanowire. These materials are considered as interesting options for advanced semiconductors, such as for optoelectronic applications. Their primary fabrication method however is based on chemical vapor deposition or of etching of a semiconductor substrate. It would be efficient, if these nanomaterials could be made separately, and subsequently be integrated by wet-chemical deposition. The present invention allows this. One example hereof uses nanowires may be manufactured by dry etching from a semiconductor substrate. After removal of the nanowires from the substrate into a dispersion, they may be provided with a surface layer by adding ammonia and a tetraethoxyorthosilicate, or a derivatized orthosilicate to the dispersion. The derivatized orthosilicate may include reactive end groups as discussed above. Alternatively, the nanowire with the derivatized orthosilicate may undergo a further reaction to be provided with desired reactive end groups for integration as part of the self-assembled system. The example to provide nanowires with a functionalized surface, such as oxide or a derivative thereof, such as that obtained with a sol-gel reaction of (3-aminopropyl)-triethoxysilane to the nanowire, is known per se from WO-A 2004/046021, the contents of which are herein included by reference.

These and other aspects of the invention will be further elucidated with reference to the Figures, in which:

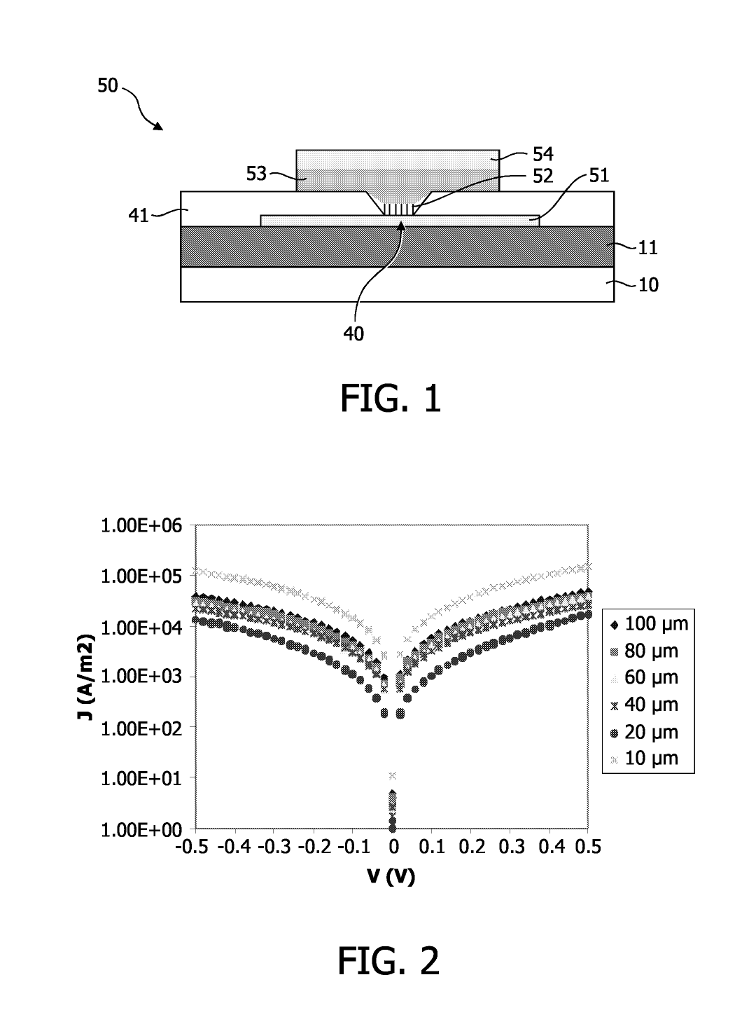

FIG. 1 shows in cross-sectional view a first embodiment of the element of the invention;

FIG. 2 shows a graph of the current density of the thus formed electrical element (capacitor) as a function of the applied bias voltage.

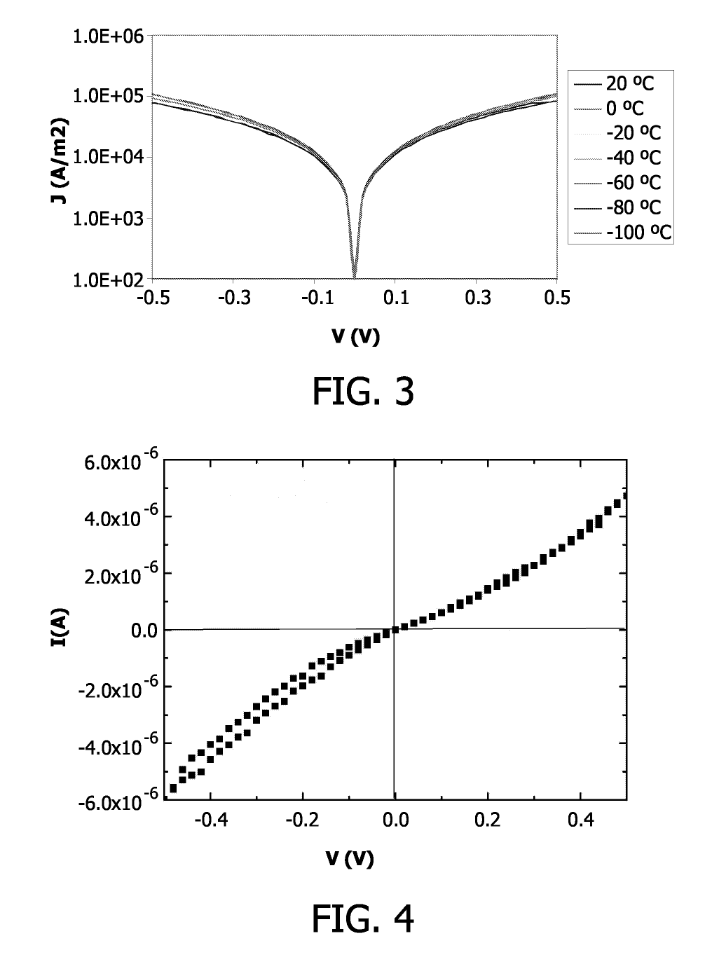

FIG. 3 shows a graph of the current density for an element 50 with a cavity 40 of 20 microns diameter as a function of the applied bias voltage for several temperatures.

FIG. 4 shows another graph of the current density as a function of the applied bias voltage.

FIG. 1 shows in cross-sectional and diagrammatical view a first embodiment of the element of the invention. The Figure is not drawn to scale. The element 50 was made on a substrate 10 of silicon with a diameter of 4 inch (10 cm). The substrate 10 was passivated with a thermally grown layer 11 of SiO₂. A first, bottom electrode 51 was made by thermal evaporation of 1 nm of chromium and of 40 nm of gold, followed by photolithography. Subsequently, a cavity 40 was defined in an electrically insulating layer 41. A negative photoresist was used as the insulating layer 41. Cavities 40 with several diameters from 1 to 100 micron were defined. A self-assembled system 52 was applied in the thus formed cavity 40. The system 42 was in this embodiment a monolayer. Use was made of 1,8-octanedithiol and 1,12-dodecanedithiol and dodecanethiol in different embodiments. Subsequently, a composition of an electrically conducting material is spin coated to form a polymeric contact layer 53. The composition contained a mixture of poly(3,4-ethylenedioxythiophene) and polystyrene sulphonic acid—also referred to as PEDOT/PSS—as supplied by H. C. Starck A. G. Two drops of a surfactant (FSO100, DuPont) is added to the dispersion in order to decrease the surface tension and hence to improve the wetting of PEDOT/PSS in the cavity 40. A top electrode 54 is applied hereon by evaporation and patterned by photolithography. Finally, reactive ion etching (O2 plasma, 5 min, 9 sccm, 0.009 mbar) is used to pattern the contact layer 53. In this step the gold top electrode 54 functions as an etch mask.

FIG. 2 shows a graph of the current density of the thus formed electrical element (capacitor) as a function of the applied bias voltage. The graph is based on the experiments with 1,12-dodecanedithiol. The data shows scaling of the resistance with the size of the contact cavities 40. The robustness of the technology can be inferred from the lack of shorts in the element 50 with a cavity of 100 microns. The transport was measured up to a bias of 0.5 V. The measurements were performed at room temperature in ambient conditions.

FIG. 3 shows a graph of the current density for an element 50 with a cavity 40 of 20 microns diameter as a function of the applied bias voltage for several temperatures. Use is made of 1,12-dodecanedithiol as the self assembled system. The measurements were performed in vacuum. Firstly, the current density increases in vacuum as can be seen from comparison of FIGS. 2 and 3. The current density obtained in vacuum is comparable to that expected from literature data. Secondly, the transport does not depend on temperature. This clearly indicates that the transport is dominated by tunneling. Finally, we note that measurements in ambient conditions sometimes show a negative differential resistance at a bias of around 1 V. This might be an artefact of the water. In vacuum the negative differential resistance disappears.

FIG. 4 shows another graph of the current I (A) as a function of the applied bias voltage. This graph is based on an experiment on dodecanethiol, thus a monothiol. The structure appears to operate as a tunnel diode. The current versus applied voltage (I-V) characteristic of a MIM diode (100 microns in diameter) based on dodecanedithiol shows a non-linear increase of the current with the applied voltage. The absence of any temperature dependence over the range from 199 to 293 K for the I-V measurements demonstrates that non-resonant tunnelling is the dominant transport mechanism in these devices.

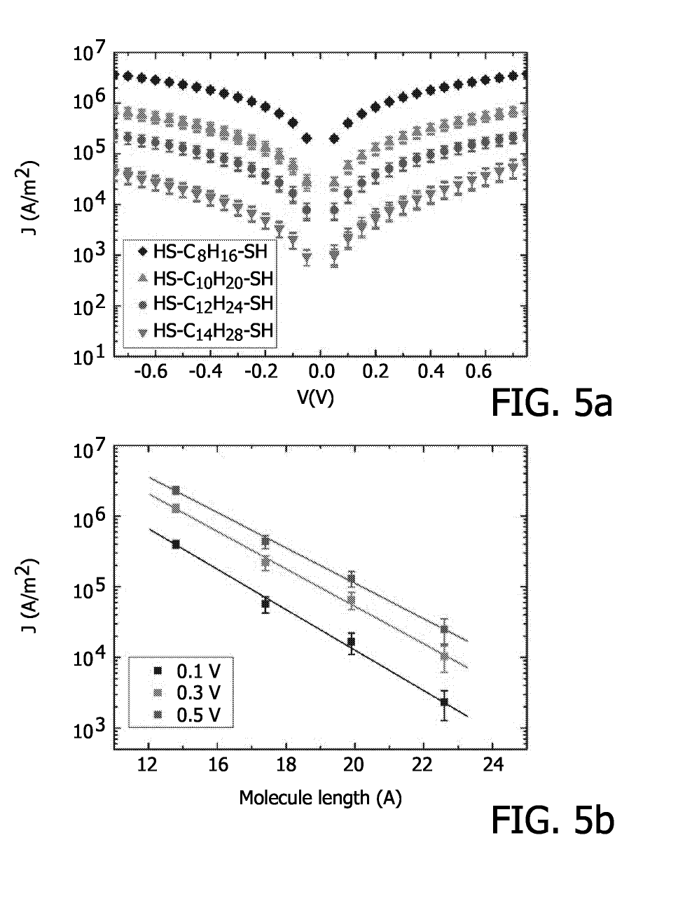

FIG. 5a shows a graph in which the current density J is shown in relation to the applied voltage (V). Measurements are shown for different alkanedithiols, e.g. octanedithiol, decanedithiol, dodecanedithiol and tetradecanedithiol with lateral dimensions ranging from 10 to 100 micrometer in diameter. The graph is averaged over at least 17 devices and error bars are included. A decrease of the current density with the length of the alkanedithiol is found. The length of the alkanedithiol appears thus a good measure of the tunnel barrier thickness.

FIG. 5b shows a graph in which the current density J is plotted against the molecular lengths for different bias voltages. The applied bias voltages are 0.1, 0.3 and 0.5 V. The current density J is plotted on a logarithmic scale. A linear fit through the data shows that the current density depends exponentially on the barrier thickness. This strong dependence on molecule length confirms that the measured currents are indeed specific for the molecule in the junction instead of the molecule/interface related properties.

1. A method of manufacturing an electrical device comprising an electrical element, the electrical element comprising a first and a second electrode and an intermediate self-assembled system, comprising the steps of:
providing a substrate with the first electrode;
providing the self-assembled system on the first electrode,
applying a composition that comprises an organic material by wet-chemical deposition on the self-assembled system, so as to form an electrically conductive contact layer that comprises a polymer material, and
depositing the second electrode on the electrically conductive contact layer.

2. A method as claimed in claim 1, wherein the self-assembled system comprises a monolayer that is formed on the first electrode by self-assembly.

3. A method as claimed in claim 1, wherein the composition comprises a polar solvent.

4. A method as claimed in claim 1, wherein a patterned dielectric layer is provided on the substrate with the first electrode, such that the first electrode is at least partially exposed, after which the self-assembled system is provided on the exposed portion of the first electrode and the electrically conductive contact layer is provided to extend on the self-assembled system and on the dielectric layer.

5. A method as claimed in claim 1, wherein the organic material is an electrically conductive polymer.

6. A method as claimed in claim 5, wherein the composition further comprises a polymeric acid material, which acts as a dopant for the electrically conductive polymer.

7. A method as claimed in claim 5, wherein the electrically conductive polymer is a poly(3,4-alkylenedioxythiophene), wherein the alkylenegroup is chosen from the group consisting of an optionally C₁ to C₁₂- alkyl- or phenylsubstituted methylene group, an optionally C₁ to C₁₂-alkyl- or phenylsubstituted 1,2-ethylene group, a 1,3-propylene group and a 1,2-cyclohexylene group.

8. A method as claimed in claim 2, wherein the self-assembled system is provided with a first and a second functional group, which first functional group is part of a compound which forms the monolayer and is after the self-assembly bonded to the first electrode, which a second functional group is exposed on the self-assembled system and enables formation of a bond with the electrically conductive contact layer.

9. An electrical device obtainable by a method according to claim 1.

10. An electrical device comprising an electrical element, the electrical element comprising a first and a second electrode and an intermediate self-assembled system, wherein an electrically conductive contact layer that comprises a polymeric material is present between the self-assembled system and the second electrode.

11. An electrical device as claimed in claim 10, wherein the self-assembled system comprises a junction.

12. An electrical device as claimed in claim 10, wherein the self-assembled system comprises a carbon nanotube or nanowire.

13. An electrical device according to claim 10 comprising a substrate, the substrate being present on the side of the first electrode that is opposite to the side of the first electrode on which the self-assembled system is present.
